(19) United States
(12) Patent Application Publication
(10) Pub. No.: US 2014/0327126 A1
(43) Pub. Date: Nov. 6, 2014

(54) COOLING INTEGRATED CIRCUIT PACKAGES FROM BELOW

(71) Applicant: Microsoft Corporation, (US)

(72) Inventors: Susheela N. Narasimhan, Fremont City, CA (US); Jelenal H. Larsen, Los Gatos, CA (US)

(73) Assignee: Microsoft Corporation, Redmond, WA (US)

(21) Appl. No.: 13/874,991

(22) Filed: May 1, 2013

(51) Int. Cl. H01L 23/36

(52) U.S. Cl. CPC H01L 23/36
USPC 257/690

(57) ABSTRACT

The subject disclosure is directed towards cooling an integrated circuit package such as a flip chip ball gate array from beneath the package. The integrated circuit package comprises a silicon die, and a substrate below the silicon die. The substrate includes microvias configured to transfer heat away from the silicon die in a direction towards the circuit board for cooling the silicon die from beneath. The circuit board may likewise contain vias or share common vias with the package to facilitate cooling from beneath the circuit board.

### BACKGROUND

In integrated circuits such as microprocessors used on printed circuit boards, the various components that generate heat (e.g., flip chip packages) need to be cooled. For example, as flip chip packages have become more powerful, their power dissipation has increased around an order of magnitude, e.g., from 10-20 Watts to 100-150 Watts in the last dozen years or so.

At the same time, consumers want almost any consumer device to be as small as physically possible, such as to fit into narrow spaces in entertainment centers and the like. Gaming consoles in particular are expected by consumers to be extremely powerful, yet remain small in size as well as quiet in operation from an acoustical standpoint. The cooling of high wattage chips is thus a challenging problem.

Conventional cooling solutions for flip chip packages mostly focus on heatsink/fan solutions that cool the top side of the package. Liquid cooling solutions exist, but have not succeeded in the industry due to issues of leakage, reliability and so forth. Thus, although the practical limits of air cooling are being rapidly reached, air cooling remains the solution used in contemporary electronic devices, and improvements in this technology area are thus desirable.

### SUMMARY

This Summary is provided to introduce a selection of representative concepts in a simplified form that are further described below in the Detailed Description. This Summary is not intended to identify key features or essential features of the claimed subject matter, nor is it intended to be used in any way that would limit the scope of the claimed subject matter.

Briefly, various aspects of the subject matter described herein are directed towards an integrated circuit package configured to couple to a circuit board. The integrated circuit package comprises a silicon die, and a substrate below the silicon die. The substrate includes microvias configured to transfer heat away from the silicon die in a direction towards the circuit board for cooling the silicon die from beneath.

In one aspect, an integrated circuit package is configured to couple to a circuit board, in which the integrated circuit package includes a die that generates heat. A substrate layer adjacent the die and a support structure layer couples the substrate to the circuit board. The package, when coupled to the circuit board, includes a plurality of vias (e.g., microvias), including vias through at least the substrate and vias through the circuit board. The vias are configured to transfer heat from the die to the opposite side of the circuit board to which the package is coupled.

In one aspect, a flip chip ball gate array is incorporated into a package containing vias configured to transfer heat to below the package. A circuit board to which the package may be coupled includes vias configured to transfer at least some of the heat transferred from the package to below the circuit board.

Other advantages may become apparent from the following detailed description when taken in conjunction with the drawings.

### BRIEF DESCRIPTION OF THE DRAWINGS

The present invention is illustrated by way of example and not limited in the accompanying figures in which like reference numerals indicate similar elements and in which:

FIG. 1 is a side view representation of an integrated circuit package coupled to a circuit board, in which the package and circuit board include vias configured to transfer heat to below the circuit board for cooling the package from below in conjunction with cooling from above, and the package includes solder balls and a solder pad below the boards with solder balls attached to the vias inside the board, according to one example implementation.

FIG. 2 is a side view representation of an integrated circuit package coupled to a circuit board, in which the package and circuit board have common and/or aligned vias configured to transfer heat to below the circuit board for cooling the package from below in conjunction with cooling from above, and the package includes a solder pad and vias from the bottom of the die active side to a solder pad below the board with no solder balls below the board, according to one example implementation.

FIG. 3 is a side view representation of an integrated circuit package coupled to a circuit board, in which the package and circuit board include vias configured to transfer heat to below the circuit board for cooling the package from below independent of any cooling from above, and the package includes solder balls and a solder pad below the boards with solder balls attached to the vias inside the board, according to one example implementation.

FIG. 4 is a side view representation of an integrated circuit package coupled to a circuit board, in which the package and circuit board have common and/or aligned vias configured to transfer heat to below the circuit board for cooling the package from below independent of any cooling from above, according to one example implementation, and the package includes a solder pad and vias from the bottom of the die active side to a solder pad below the board with no solder balls below the board, according to one example implementation.

FIG. 5 is a block diagram representing an example non-limiting computing system or operating environment (e.g., in the form of a gaming console) in which one or more aspects of various embodiments described herein can be implemented.

### DETAILED DESCRIPTION

Various aspects of the technology described herein are generally directed towards dissipating heat for integrated circuits including flip chip/ball gate array (BGA) packages from below, e.g., below the circuit board. The technology leverages the heat dissipated from the active side of the device on the bottom side of the die, which is in contact with the substrate. This provides another mechanism for cooling and thus provides a compact, elegant and effective cooling solution.

Note that as used herein, the concept of “below” may be relative to an actual position of a device or the like that houses the circuitry. Thus, even if the chip and circuit board were turned over or sideways, or even if the chip was mounted underneath the circuit board, the chip is still considered cooled from the opposite side of the circuit board to which the chip is coupled. Thus, for brevity, “below” the board is considered the same as from the “opposite side” of the board relative to the chip.

It should be understood that any of the examples herein are non-limiting. For instance, examples used herein refer to a motherboard-mounted flip chip ball gate array (BGA), however the technology may apply to other configurations such as other types of circuit boards and integrated circuit chips. As such, the present invention is not limited to any particular embodiments, aspects, concepts, structures, functionalities or examples described herein. Rather, any of the embodiments, aspects, concepts, structures, functionalities or examples described herein are non-limiting, and the present invention may be used various ways that provide benefits and advantages in integrated circuits and/or cooling in general.

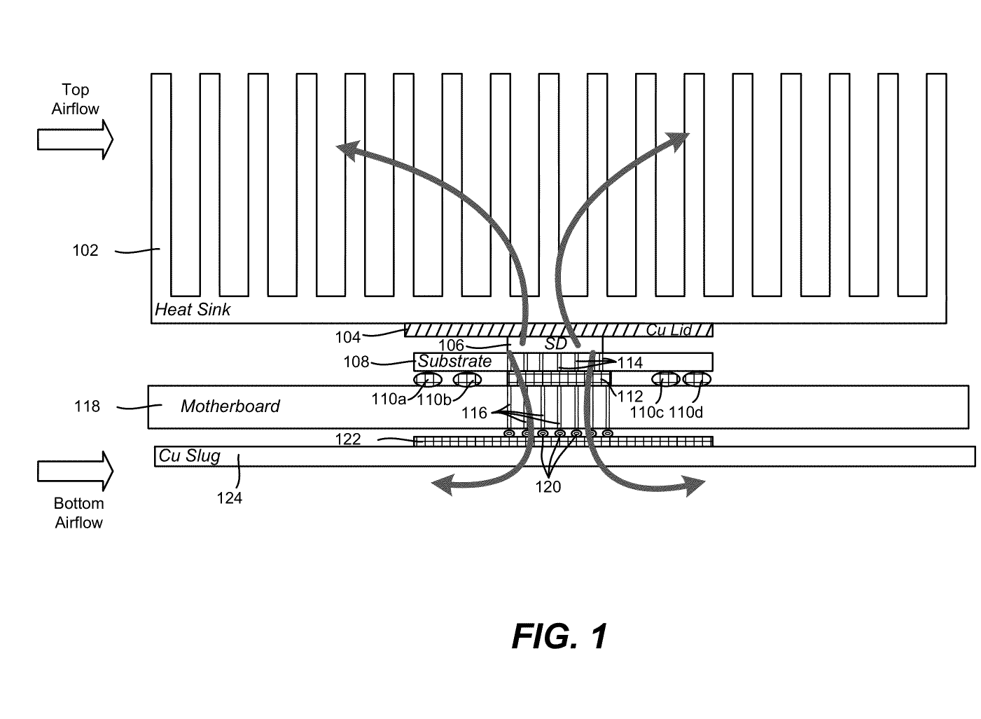

FIG. 1 is a side view illustrating example concepts of various aspects of the technology described herein. The implementation exemplified in FIG. 1 may be applicable for use with high power components (e.g., 120 W or more), and thus may be used in gaming consoles and in other computer and networking environments,

In general, from the top down in the drawing, a heatsink 102 may be physically coupled to a package lid 104, e.g., a copper lid. Note that while copper is used as one reasonably desirable alternative, other materials including alloys and compounds may be used. This allows for conventional cooling, e.g., via a top airflow. Note that the arrow labeled “Top Airflow” in FIG. 1 is only for purposes of an example, and airflow via a fan or the like may be in any one or more directions.

In the example implementation of FIG. 1, bottom airflow is also provided and/or leveraged for cooling, and thus as described herein, is able to assist in the chip cooling. To this end, the silicon die (SD) 106 is coupled to a substrate 108 comprising any suitable material. In a package such as a flip chip BGA, the substrate lies on package solder balls (four are exemplified as 110a-110d) as well as a solder pad 112, e.g., in the center of the package. The package solder balls 110a-110d and/or the solder pad 112 provide a support structure layer that couples the substrate to the circuit board (motherboard) 118.

To help convey the heat away (as represented by the curved gray arrows) from the silicon die 106, microvias 114 (not all illustrated are labeled) are provided inside the substrate 108, below the active side of the silicon die SD 106. Further, microvias 116 (or possibly standard vias, with not all labeled) inside the circuit board (e.g., motherboard 118) allow heat to transfer through the motherboard 118. In this implementation, first and second sets of vias are provided.

Bottom solder balls 120 (not all illustrated are labeled) are attached to microvias 116 on the back side of the motherboard 118 and attached to a lower solder pad 122 below the lower solder balls 120. To help dissipate the heat, a mechanism that basically acts as a bottom lid 124, such as a copper slug (or ceramic material, arsenic, or the like) is attached to the solder pad 122, although as is understood, alternative materials may be used. A further heatsink below the motherboard and/or bottom lid 124 or (not shown) may be used.

In practice, the above design creates an effective heat transfer path below the board. The design also allows for reducing the height of the thermal solution (e.g., heatsink) on the top side of the board. The addition of the bottom airflow thus results in the ability to use higher wattage chips, and/or a consumer product design such as a gaming console that is considerably shorter in height relative to contemporary designs.

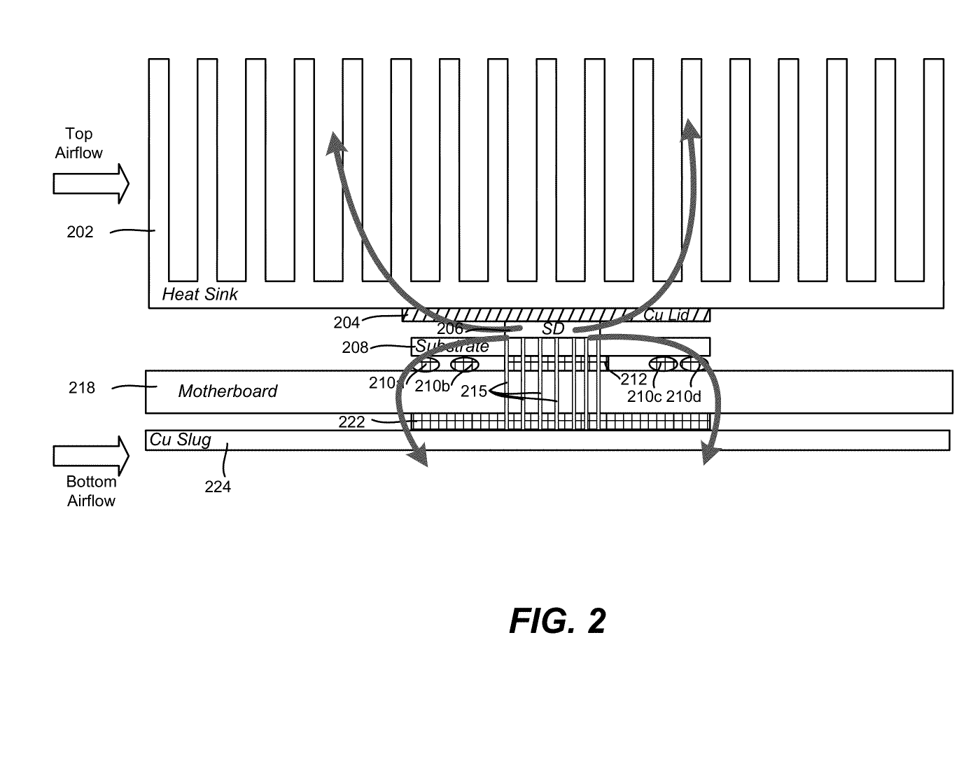

FIG. 2 shows another alternative solution in which bottom airflow is also provided and/or leveraged for cooling. FIG. 2 is also generally intended for use in cooling high power components (e.g., on the order of 120 W) and thus may be used in entertainment/gaming consoles and other computer and networking environments. Note that in FIG. 2, components similar to those in FIG. 1 are labeled 2xx instead of 1xx.

As in FIG. 1, in FIG. 2 below the heatsink 202 and the lid 204, the silicon die SD 206 is coupled to a substrate 208. The substrate 208 is soldered on the package solder balls 210a-210d as well as a solder pad 212, e.g., in the center of the package. The package solder balls 210a-210d and/or the solder pad 212 provide a support structure layer that couples the substrate to the circuit board (motherboard) 218.

Microvias 215 are provided through the substrate 208, the solder pad 212, the motherboard 218 and the lower solder pad 222. Thus, there is only one set of vias all the way through from the substrate 108 through the motherboard 218. Note that if desirable for manufacturing purposes, separate vias through each component may be used, however as can be readily appreciated, if separate, some consideration as to how the separate vias are aligned in a pattern will likely provide for more optimal cooling. In such an event, because the separate vias generally couple together to provide a more direct path, they are considered to be a single set of vias 215. A heat transfer mechanism such as a copper slug 224 attached to the motherboard material by a lower solder pad 222 (or otherwise coupled to the motherboard material) helps to dissipate the heat.

Note that in FIG. 2, the bottom solder balls have been eliminated with respect to FIG. 1, e.g., with the exemplified solder pad 222 directly soldered to the bottom of board. This is only one alternative, and a combination of using at least some solder balls along with vias through at least some of the various components may be used. For example, vias may go through the upper solder pad 112 of FIG. 1, yet be used with direct lower solder pad coupling as in FIG. 2.

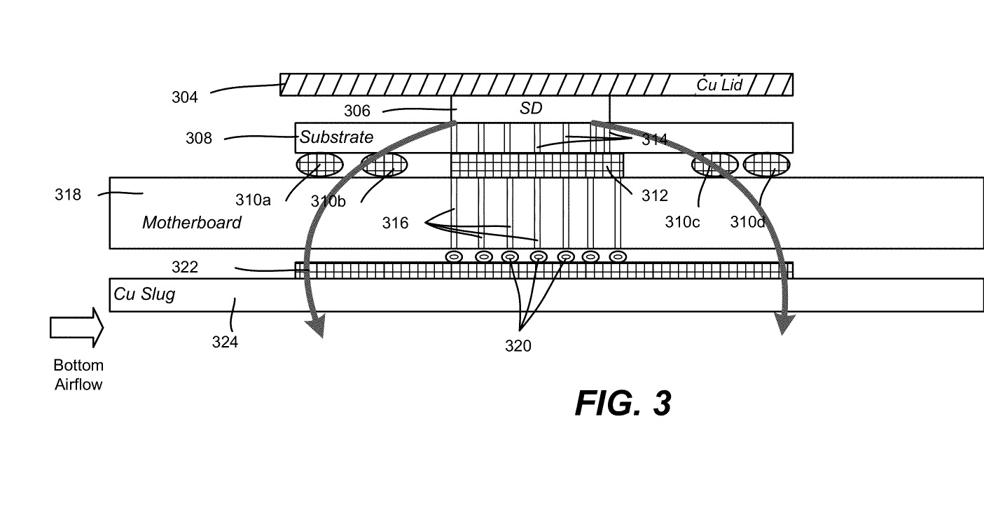

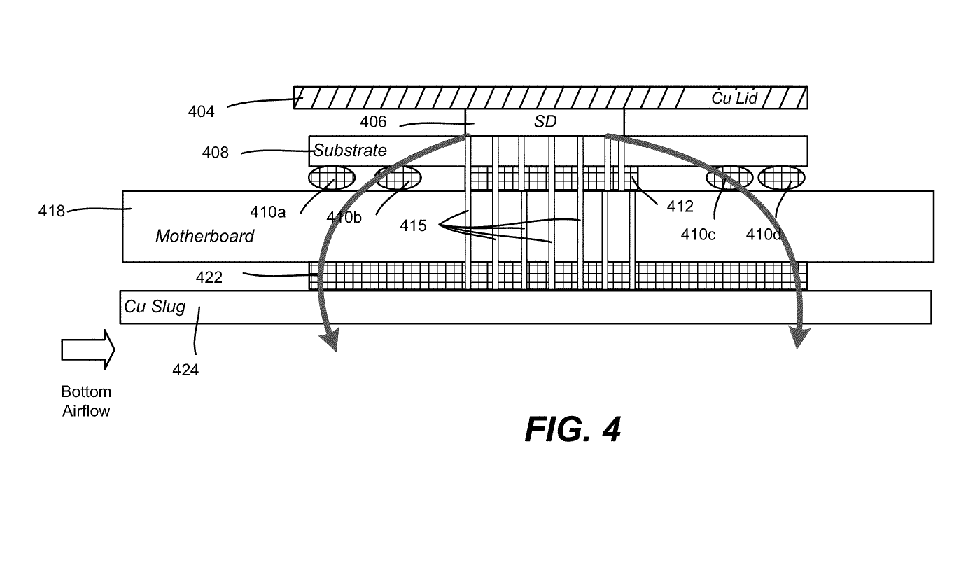

FIGS. 3 and 4 illustrate other alternatives, in which no upper heatsink exists for a given package. FIGS. 3 and 4 thus are generally intended as a heat transfer mechanism for somewhat lower power components, e.g., as in smaller consoles (such as Microsoft Corporation's Kinect™-based technology), cell phones and so forth. Further, the implementations of FIGS. 3 and 4 may be used in combination with the generally higher power components corresponding to FIGS. 1 and 2, such as in the same device/environment.

As can be seen, FIG. 3 corresponds to the lower components of FIG. 1 and FIG. 4 corresponds to the lower components of FIG. 2, respectively, with the components labeled 3xx and 4xx instead of 1xx and 2xx, respectively.

As can be seen the microvias provide for transferring heat to the bottom of the package. In general, microvias are provided through the substrate, one or more solder pads, and/or circuit board, and thus are part of the overall design of the package. Notwithstanding, conventional construction techniques may be used; for example, via known techniques, the vias may be drilled, followed by plating and surfacing, with the solder balls applied next.

### Example Operating Environment

It can be readily appreciated that the above-described implementation and its alternatives may be implemented within any suitable computing or electronics device having a circuit board, including a gaming system, personal computer, tablet, DVR, set-top box, smartphone, appliance, audio receiver, television and/or the like. Combinations of such devices are also feasible when multiple such devices are linked together. For purposes of description, a gaming (including media) system is described as one exemplary operating environment hereinafter. As can be readily appreciated, the various chip cooling techniques described above may be applied to any appropriate circuitry of the integrated circuits described below.

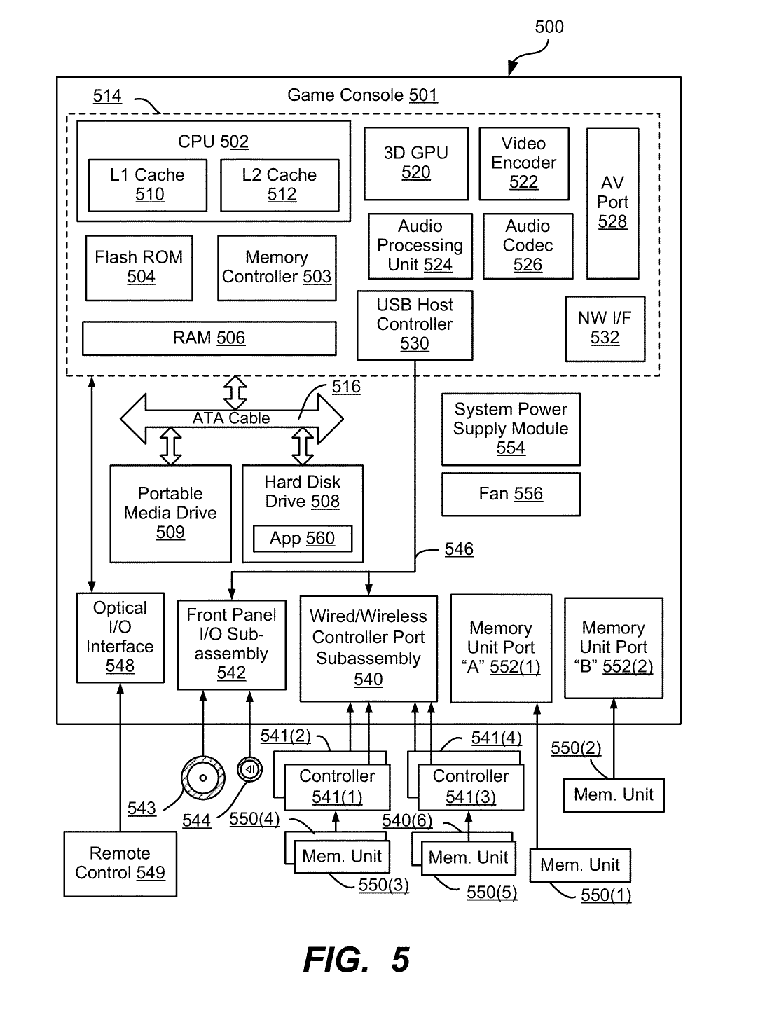

FIG. 5 is a functional block diagram of an example gaming and media system 500 and shows functional components in more detail. Console 501 has a central processing unit (CPU) 502, and a memory controller 503 that facilitates processor access to various types of memory, including a flash Read Only Memory (ROM) 504, a Random Access Memory (RAM) 506, a hard disk drive 508, and portable media drive 509. In one implementation, the CPU 502 includes a level 1 cache 510, and a level 2 cache 512 to temporarily store data and hence reduce the number of memory access cycles made to the hard drive, thereby improving processing speed and throughput.

The CPU 502, the memory controller 503, and various memory devices are interconnected via one or more buses (not shown). The details of the bus that is used in this implementation are not particularly relevant to understanding the subject matter of interest being discussed herein. However, it will be understood that such a bus may include one or more of serial and parallel buses, a memory bus, a peripheral bus, and a processor or local bus, using any of a variety of bus architectures. By way of example, such architectures can include an Industry Standard Architecture (ISA) bus, a Micro Channel Architecture (MCA) bus, an Enhanced ISA (EISA) bus, a Video Electronics Standards Association (VESA) local bus, and a Peripheral Component Interconnects (PCI) bus also known as a Mezzanine bus.

In one implementation, the CPU 502, the memory controller 503, the ROM 504, and the RAM 506 are integrated onto a common module 514. In this implementation, the ROM 504 is configured as a flash ROM that is connected to the memory controller 503 via a Peripheral Component Interconnect (PCI) bus or the like and a ROM bus or the like (neither of which are shown). The RAM 506 may be configured as multiple Double Data Rate Synchronous Dynamic RAM (DDR SDRAM) modules that are independently controlled by the memory controller 503 via separate buses (not shown). The hard disk drive 508 and the portable media drive 509 are shown connected to the memory controller 503 via the PCI bus and an AT Attachment (ATA) bus 516. However, in other implementations, dedicated data bus structures of different types can also be applied in the alternative.

A three-dimensional graphics processing unit 520 and a video encoder 522 form a video processing pipeline for high speed and high resolution (e.g., High Definition) graphics processing. Data are carried from the graphics processing unit 520 to the video encoder 522 via a digital video bus (not shown). An audio processing unit 524 and an audio codec (coder/decoder) 526 form a corresponding audio processing pipeline for multi-channel audio processing of various digital audio formats. Audio data are carried between the audio processing unit 524 and the audio codec 526 via a communication link (not shown). The video and audio processing pipelines output data to an A/V (audio/video) port 528 for transmission to a television or other display/speakers. In the illustrated implementation, the video and audio processing components 520, 522, 524, 526 and 528 are mounted on the module 514.

FIG. 5 shows the module 514 including a USB host controller 530 and a network interface (NW I/F) 532, which may include wired and/or wireless components. The USB host controller 530 is shown in communication with the CPU 502 and the memory controller 503 via a bus (e.g., PCI bus) and serves as host for peripheral controllers 534. The network interface 532 provides access to a network (e.g., Internet, home network, etc.) and may be any of a wide variety of various wire or wireless interface components including an Ethernet card or interface module, a modem, a Bluetooth module, a cable modem, and the like.

In the example implementation depicted in FIG. 5, the console 501 includes a controller support subassembly 540, for supporting four game controllers 541(1)-541(4). The controller support subassembly 540 includes any hardware and software components needed to support wired and/or wireless operation with an external control device, such as for example, a media and game controller. A front panel I/O subassembly 542 supports the multiple functionalities of a power button 543, an eject button 544, as well as any other buttons and any LEDs (light emitting diodes) or other indicators exposed on the outer surface of the console 501. The subassemblies 540 and 542 are in communication with the module 514 via one or more cable assemblies 546 or the like. In other implementations, the console 501 can include additional controller subassemblies. The illustrated implementation also shows an optical I/O interface 548 that is configured to send and receive signals (e.g., from a remote control 549) that can be communicated to the module 514.

Memory units (MUs) 550(1) and 550(2) are illustrated as being connectable to MU ports “A” 552(1) and “B” 552(2), respectively. Each MU 550 offers additional storage on which games, game parameters, and other data may be stored. In some implementations, the other data can include one or more of a digital game component, an executable gaming application, an instruction set for expanding a gaming application, and a media file. When inserted into the console 501, each MU 550 can be accessed by the memory controller 503.

A system power supply module 554 provides power to the components of the gaming system 500. A fan 556 cools the circuitry within the console 501.

An application 560 comprising machine instructions is typically stored on the hard disk drive 508. When the console 501 is powered on, various portions of the application 560 are loaded into the RAM 506, and/or the caches 510 and 512, for execution on the CPU 502. In general, the application 560 can include one or more program modules for performing various display functions, such as controlling dialog screens for presentation on a display (e.g., high definition monitor), controlling transactions based on user inputs and controlling data transmission and reception between the console 501 and externally connected devices.

The gaming system 500 may be operated as a standalone system by connecting the system to high definition monitor, a television, a video projector, or other display device. In this standalone mode, the gaming system 500 enables one or more players to play games, or enjoy digital media, e.g., by watching movies, or listening to music. However, with the integration of broadband connectivity made available through the network interface 532, gaming system 500 may further be operated as a participating component in a larger network gaming community or system.

### CONCLUSION

While the invention is susceptible to various modifications and alternative constructions, certain illustrated embodiments thereof are shown in the drawings and have been described above in detail. It should be understood, however, that there is no intention to limit the invention to the specific forms disclosed, but on the contrary, the intention is to cover all modifications, alternative constructions, and equivalents falling within the spirit and scope of the invention.

What is claimed is:

1. A system comprising:
an integrated circuit package configured to couple to a circuit board, the integrated circuit package including a die that generates heat, a substrate layer adjacent the die, and a support structure layer that couples the substrate to the circuit board, and
a plurality of vias, including vias through at least the substrate and vias through the circuit board, the vias configured to transfer heat from the die to the opposite side of the circuit board to which the package is coupled.

2. The system of claim 1 wherein the plurality of vias comprise microvias or standard vias, or a combination of both microvias and standard vias.

3. The system of claim 1 wherein the support structure layer comprises a first solder pad, and wherein the substrate is coupled to the circuit board by the first solder pad.

4. The system of claim 1 wherein the plurality of vias comprises a first set of vias through the substrate and a second set of vias through the circuit board.

5. The system of claim 1 wherein the plurality of vias comprise at least some vias that extend through the substrate, the support structure layer and the circuit board.

6. The system of claim 1 wherein the opposite side of the circuit board is coupled to a heat transfer mechanism.

7. The system of claim 6 wherein the heat transfer mechanism is coupled to or comprises a lower heat sink.

8. The system of claim 1 wherein the opposite side of the circuit board is coupled to a heat transfer mechanism by solder balls or a lower solder pad, or both solder balls and a lower solder.

9. The system of claim 1 wherein the opposite side of the circuit board is coupled to a heat transfer mechanism by a lower solder pad.

10. The system of claim 9 wherein the lower solder pad includes vias for transferring heat to the heat transfer mechanism.

11. The system of claim 1 wherein the package further comprises a top lid coupled to the die, and wherein the top lid is further coupled to an upper heat sink.

12. An integrated circuit package configured to couple to a circuit board, the integrated circuit package comprising, a silicon die, and a substrate below the silicon die, the substrate including microvias configured to transfer heat away from the silicon die in a direction towards the circuit board for cooling the silicon die from beneath.

13. The integrated circuit package of claim 12 wherein the silicon die and substrate are incorporated into a flip chip ball gate array.

14. The integrated circuit package of claim 12 wherein the substrate is coupled to the circuit board through a solder pad.

15. The integrated circuit package of claim 14 wherein the microvias extend through the solder pad.

16. The integrated circuit package of claim 12 wherein the circuit board includes microvias configured to transfer heat to below the circuit board.

17. The integrated circuit package of claim 12 further comprising an upper lid above the silicon die, wherein the upper lid is coupled to a heatsink to transfer heat away from the silicon die in an upwards direction.

18. A system comprising, flip chip ball gate array configured for coupling to a circuit board, the flip chip ball gate array incorporated into a package containing vias configured to transfer heat to below the package, the circuit board having vias configured to transfer at least some of the heat transferred from the package to below the circuit board.

19. The system of claim 18 wherein the package vias and the circuit board vias comprise at least some common vias drilled through the substrate, the circuit board and any intermediate layer or layers between the substrate and circuit board.

20. The system of claim 18 wherein the package vias and the circuit board vias comprise at least some separate vias, and wherein the separate vias transfer heat through at least one intermediate layer between the substrate and circuit board.
